(19) United States
(12) Patent Application Publication
(10) Pub. No.: US 2010/0090699 A1
(43) Pub. Date: Apr. 15, 2010

(54) POWER SUPPLY FOR RF COILS

(75) Inventors: Paulus Cornelius Hendrikus Adrianus Haans, Eindhoven (NL); Marc Paul Saes, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/520,163

(22) PCT Filed: Dec. 20, 2007
(86) PCT No.: PCT/IB07/55251

§ 371 Date: Jun. 19, 2009

(30) Foreign Application Priority Data
Dec. 21, 2006 (EP) 06126933.8

(51) Int. Cl. G01R 33/36; G01R 33/34

(52) U.S. Cl. 324/322

(57) ABSTRACT

A radio-frequency (RF) coil array for receiving magnetic resonance (MR) signals wherein the RF coil array (402) comprises at least one RF receive coil with an associated electronic circuit, a rechargeable electrical storage device arranged to supply electrical power to the associated electronic circuit, and a charging circuit arranged to charge the rechargeable electrical storage device, wherein the charging circuit includes a switching circuit (102SW1, 102SW2, 104SW1, 104SW2, 106SW1, 106SW2, 108SW1, 108SW2) configured to electrically isolate the charging circuit from the RF coil array at least when the RF receive coil is receiving MR signal. During a time period when the RF receive coil is not receiving MR signal and/or when another RF coil is not transmitting RF signals in the presence of the RF receive coil, the switching circuit switches the charging circuit to an ON state which enables the charging circuit to charge the rechargeable electrical storage device.

### FIELD OF THE INVENTION

The invention relates to the field of magnetic resonance (MR), particularly to power supplies for radio-frequency (RF) coil electronics.

### BACKGROUND OF THE INVENTION

The international patent application WO 2006/000928 A2 discloses an RF receive coil for receiving a magnetic resonance signal, the RF antenna including one or more electrical conductors, at least one of which is a substantially hollow conductor. At least one electronic component, for example, a battery or a storage capacitor, is disposed inside the substantially hollow conductor of the RF antenna for operating the RF antenna. In some embodiments, the battery or storage capacitor is charged by the RF excitation phase of the magnetic resonance imaging sequence, that is, the battery or capacitor is charged by the RF transmitter during MR excitation. In yet another embodiment, the battery or capacitor is charged over the RF cable between scans.

### SUMMARY OF THE INVENTION

In the embodiments disclosed above, the presence of electrical wires used for charging the battery or capacitor, especially close to the RF receive coil, can cause common-mode currents to flow through the wires. For example, the common-mode currents could couple with the receive coil, thereby affecting the performance of the receive coil, thereby giving rise to artifacts in acquired MR images.

It is thus desirable to have a charging circuit that can be configured to prevent the flow of common-mode currents when the RF receive coil is receiving MR signal, which may be achieved by switching the charging circuit between at least two different states, for example, ON and OFF. In one state, for example the ON state, the charging circuit would charge the battery or storage capacitor, while in the other state, for example the OFF state, the charging circuit would be electrically isolated so as to disable the flow of common-mode currents through the wires of the charging circuit.

Accordingly, an RF coil array for receiving an MR signal is disclosed herein, wherein the RF coil array comprises at least one RF receive coil with an associated electronic circuit, a rechargeable electrical storage device arranged to supply electrical power to the associated electronic circuit, and a charging circuit arranged to charge the rechargeable electrical storage device, wherein the charging circuit includes a switching circuit configured to electrically isolate the charging circuit from the RF coil array at least when the RF receive coil is in operation.

During a time period when the RF receive coil is not receiving MR signal, and when no other RF coil is transmitting RF signal in the presence of the RF receive coil, the switching circuit switches the charging circuit to an ON state which enables the charging circuit to charge the rechargeable electrical storage device. When the RF receive coil is receiving MR signal, the switching circuit switches the charging circuit to an OFF state, thereby disabling the flow of common-mode currents in the charging circuit. Similarly, the switching circuit also switches the charging circuit to the OFF state when the RF coil array is in the presence of another RF coil that is transmitting RF signal to a subject under examination. Thus, charging of the rechargeable electrical storage device takes place in the absence of both RF transmission to the subject and reception of MR signals from the subject. Such a time period, when no RF signals are transmitted and no MR signals are received, is available during an MR examination, either between consecutive pulse sequences or as a “dead time” during a particular pulse sequence.

Furthermore, a method of supplying electrical power to an RF coil array in an MR system is also disclosed herein, wherein the RF coil array comprises at least one RF receive coil with an associated electronic circuit, and wherein a rechargeable electrical storage device is configured to supply electrical power to the associated electronic circuit. The method comprises operating a charging circuit to charge the rechargeable electrical storage device and operating a switching circuit to isolate the charging circuit from the RF coil array at least when the RF receive coil is in operation.

Furthermore, a computer program to implement a method of supplying electrical power to an RF coil array in an MR system is also disclosed herein, wherein the RF coil array comprises at least one RF receive coil with an associated electronic circuit and wherein a rechargeable electrical storage device is configured to supply electrical power to the associated electronic circuit. The computer program comprises instructions to operate a charging circuit to charge the rechargeable electrical storage device and to operate a switching circuit to isolate the charging circuit from the RF coil array at least when the RF receive coil is in operation, when the computer program is run on a computer.

### BRIEF DESCRIPTION OF THE DRAWINGS

These and other aspects will be described in detail hereinafter, by way of example, on the basis of the following embodiments, with reference to the accompanying drawings, wherein:

FIG. 1 shows an RF coil array comprising multiple coil elements with electronics powered by local power supplies that utilize the charging circuit disclosed herein;

FIG. 2 shows the circuit diagram of a local power supply configured to generate multiple voltages;

FIG. 3 shows certain time durations during an MR pulse sequence that may be used for charging one or more rechargeable electrical storage devices in the RF coil array; and

FIG. 4 shows an MR system comprising an RF coil array including a charging circuit as disclosed herein.

Corresponding reference numerals when used in the various figures represent corresponding elements in the figures.

### DETAILED DESCRIPTION OF EMBODIMENTS

The electronic circuitry associated with RF coils may contain various electronic circuits like preamplifier circuits, tune-detune switches, and/or other analogue or digital signal processing circuits. All these electronic circuits need power to operate, typically DC, which may be supplied in a variety of ways.

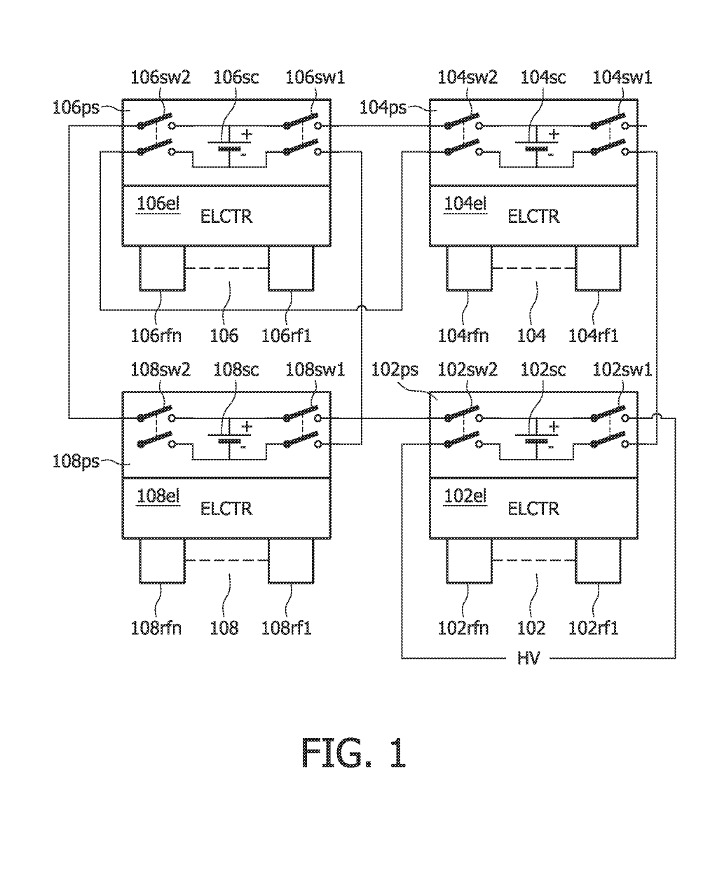

One way of supplying the required electrical power is via conducting wires leading from a main power supply to the RF coils. However, the conducting wires could interact with the RF fields generated by the RF coils, thereby posing a threat to safety of a subject being examined by the RF coil array and/or it could lead to artifacts in the acquired MR images. Another way to provide the required power is by using local power supplies such as batteries or capacitors. The batteries or capacitors could be rechargeable so as to reduce the need to replace them on a frequent basis. The rechargeable local power supplies can then be charged periodically to provide power to the associated electronic circuitry when required. Such recharging can be achieved by providing a charging circuit as shown in FIG. 1, wherein rechargeable electrical storage devices like capacitors or storage batteries that are present in close proximity to the electronic circuits are supplied with power from a main power source.

In brief, FIG. 1 shows an RF coil array comprising multiple RF coils divided into four sets 102, 104, 106 and 108. Each set of coils includes multiple RF coils or coil elements 102rf1 to 102rfn, 104rf1 to 104rfn, 106rf1 to 106rfn, 108rf1 to 108rfn. The dotted lines between 102rf1 and 102rfn indicate that more than two RF coils may exist in the particular set of RF coils 102; similar inferences may be drawn for the dotted lines in the other RF coils sets 104, 106 and 108. Each set of RF coils 102, 104, 106 and 108 is associated with its own electronic circuitry denoted by 102el, 104el, 106el, and 108el, respectively. Each electronic circuit has its own local power supply depicted by 102ps, 104ps, 106ps, and 108ps, respectively. The local power supplies may be connected or disconnected from the charging circuit by respective switching circuits. In the embodiment shown in FIG. 1, there are two switching circuits for each local power supply circuit, specifically 102sw1 and 102sw2 for 102ps, 104sw1 and 104sw2 for 104ps, 106sw1 and 106sw2 for 106ps, and 108sw1 and 108sw2 for 108ps. The local power supplies and the switching circuits, together with the wires interconnecting them as well as connecting them to the main power source HV, form the charging circuit disclosed herein. A rechargable electrical storage device (102sc, 104sc, 106sc, 108sc) is provided in each local power supply circuit (102ps, 104ps, 106ps, 108ps) to store the electrical charge that will supply power to the respective electronic circuitry; specifically, the rechargable electrical storage devices 102cp, 104cp, 106cp, and 108cp provide electrical power to the electronic circuits 102el, 104el, 106el, and 108el, respectively. All the local power supplies are powered by a main power supply HV.

Even in the case of supplying power to the associated electronics using local rechargable electrical storage devices, if conducting wires are used to supply power from a main power source HV in order to recharge the rechargable electrical storage devices, then we run into the earlier-mentioned problem of the conducting wires interacting with the RF receive coil. To avoid this, the conducting wires can be prevented from interacting with the RF receive coil array by ensuring that the conducting wires are “cut” into smaller pieces that are disconnected from each other when the RF receive coil array is receiving MR signal. This can be achieved by providing a switching circuit as shown in FIG. 1, wherein the two switches connected to a particular section of the charging circuit (102sw1 and 102sw2 connected to the charging circuit of RF coil set 102) operate to disconnect the conducting wires of the charging circuit when the RF receive coil is receiving MR signal.

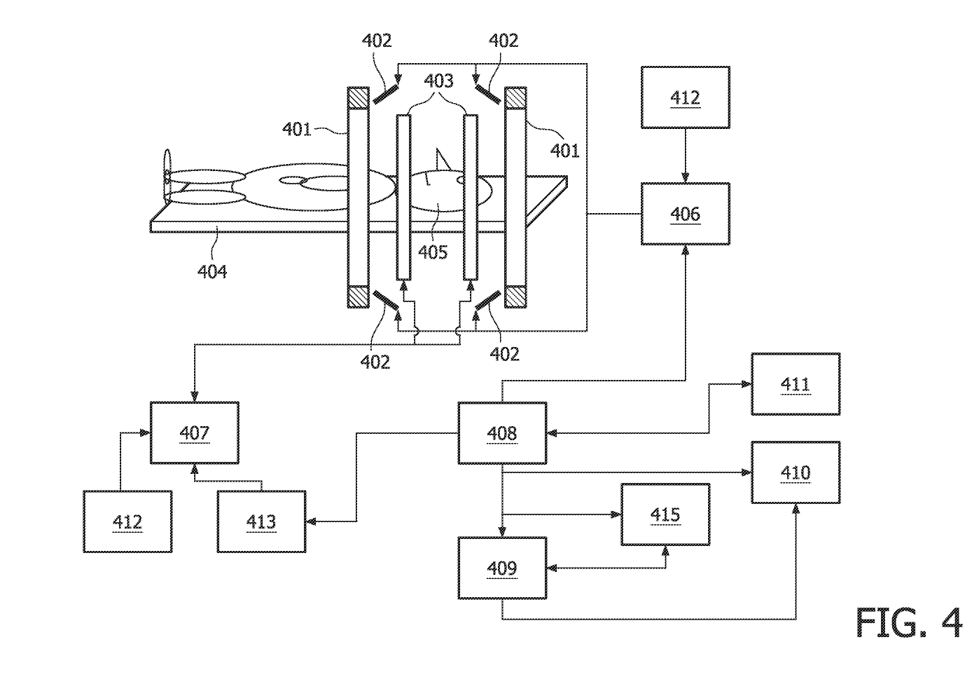

Furthermore, it is likely that the conducting wires of the charging circuit may interfere with an RF transmit coil that is used to transmit RF signal to a subject under examination (405 in FIG. 4). Such interference could lead to changes in the transmit field homogeneity, which could in turn cause unexpected increases in the local or global specific absortion rate (SAR) in the subject. The RF transmit coil may be the same as the RF receive coil array or it could be a different RF coil. Either way, it is possible to avoid interference between the charging circuit and the RF transmit coil by operating the switches (102sw1 and 102sw2, 104sw1 and 104sw2, 106sw1 and 106sw2, 108sw1 and 108sw2) such that the conducting wires are “cut” during RF transmission as well. In this embodiment, it is thus possible to take advantage of the “dead time” in an MR pulse sequence to charge the rechargeable electrical storage devices. The dead time in an MR pulse sequence may be defined as those time periods in a pulse sequence where no RF signal is transmitted by the RF transmit coil and no MR signal is being received by the RF receive coil.

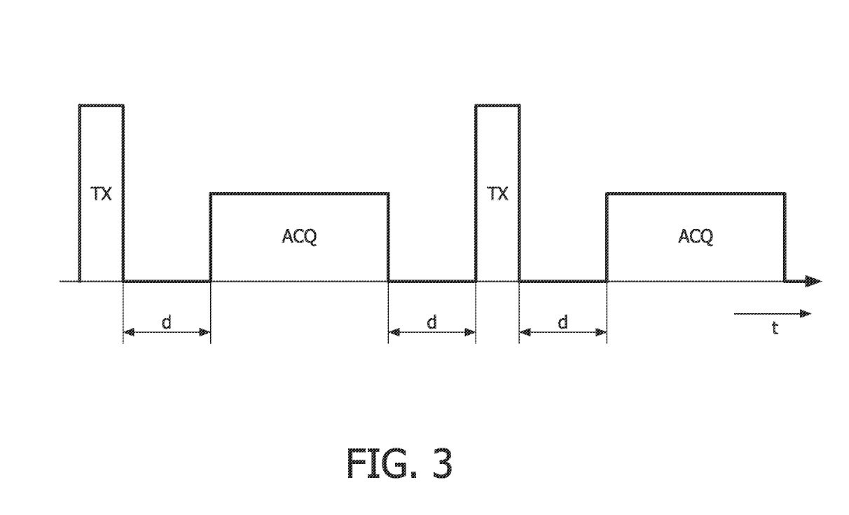

An example of such a dead time is shown as the time intervals “d” in FIG. 3, wherein the blocks TX show the transmit phase of an MR pulse sequence, during which the RF transmit coil transmits RF signals to a subject under examination (405 in FIG. 4) and the blocks ACQ show the acquisition phase of an MR pulse sequence, during which the RF receive coils receive MR signal. The axis marked “t” denotes the time axis, progressing from left to right. The time periods in between the transmit and acquisition phases, marked “d” denote the dead time when neither transmission nor reception is taking place, during which time the rechargeable electrical storage devices (102sc, 104sc, 106sc, 108sc) may be charged by the charging circuit. During the other time periods, that is during the transmission phase TX and the acqusition phase ACQ, the switching circuit in FIG. 1 is operated by opening the switches (102sw1 and 102sw2, 104sw1 and 104sw2, 106sw1 and 106sw2, 108sw1 and 108sw2) in order to “cut” the conducting wires of the charging circuit so that interference with the RF fields is minimized. Thus the charging circuit is only physically present during the charging period and becomes “RF-invisible” during other periods of time. If it is determined during fabrication of the charging circuit that, after opening the switches (102sw1 and 102sw2, 104sw1 and 104sw2, 106sw1 and 106sw2, 108sw1 and 108sw2), the remaining lengths of conducting wire in the charging circuit could have a length that could interfere with RF transmission or reception, additional switches can be incorporated in the charging circuit. By appropriately opening the switches (including the additional switches), it is possible to ensure that certain maximum allowable wire lengths are not exceeded. For example, the length of each length of wire could be made significantly shorter than one-quarter of the wavelength of the transmitted or received signal. Additionally, for effective performance, the wire lengths could also be made shorter than the lengths of the transmitting and/or receiving coils being used. This will minimize the interaction of wavelength effects, as well as interactions caused by substantially equal conductor lengths, for example the lengths of coil conductors of a typical body coil or other surface coils.

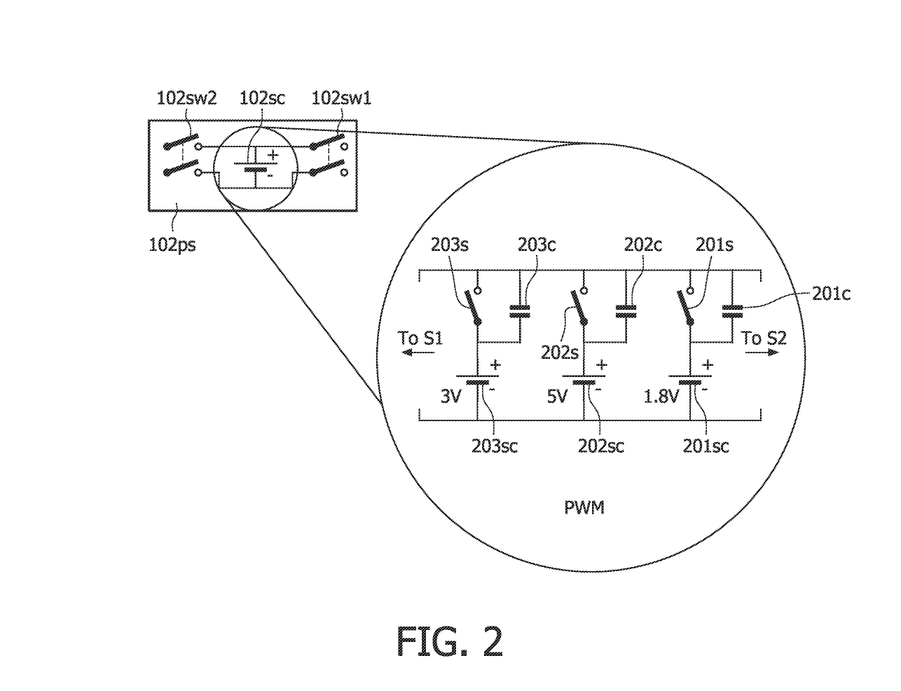

Rechargeable storage devices used to supply electrical power to electronic circuits associated with RF coils may require the capability to supply such electrical power at multiple voltages. One way of generating such multiple voltages is to use Pulse Width Modulation (or other duty-cycle affecting modulation) of the main supply voltage, and is shown in FIG. 2. Three exemplary voltages are shown, viz., 1.8 V, 3V and 5V, which are generated by the rechargeable electrical storage devices 201sc, 202sc and 203sc, respectively. Other voltages may also be generated as necessary, by using known devices like step-down converters, switched capacitor converters, or some other means of effecting DC-to-DC power conversion. The capacitors 201c, 202c and 203c, and the associated switches 201s, 202s and 203s allow the correct voltage to be selected by appropriately operating the switches 201s, 202s and 203s.

One suitable device for use as rechargeable electrical storage devices in the charging circuit of FIG. 1 is low-capacity batteries or “SuperCaps”. The range of SuperCaps which can be used is dependent on the types of circuits that need to be powered. Other electrical storage devices like rechargeable batteries may also be used, instead of, or in combination with the supercaps.

It may be noted that the charging circuit, including the switching circuit, may be constructed as a separate (stand-alone) unit that may be connected with an RF receiver coil array when the RF receiver coil array is to be used in an MR examination. The charging circuit and multiple receiver coil arrays may also be designed such that the same charging circuit may be used to charge the multiple RF receiver coil arrays, thereby minimizing overall cost. It is also possible to design the RF receiver coil array such that it is only provided with a receptable for the electrical storage device, which receptacle is appropriately connected to the associated electronics circuits. The electrical storage device, which may be obtained as a separate unit (i.e., not bundled or integrated with the RF receiver coil array), may be added separately (as-and-when required) to the receptacle in order to power the associated electronics. Such an arrangement provides the capability to replace an electrical storage device when it becomes defective, without having to replace the entire RF receiver coil array and/or the charging circuit.

FIG. 4 shows a possible embodiment of an MR system utilizing the RF coil array with a charging circuit as disclosed herein. The MR system comprises a set of main coils 401, multiple gradient coils 402 connected to a gradient driver unit 406, and RF coils 403 connected to an RF coil driver unit 407. The function of the RF coils 403, which may be integrated into the magnet in the form of a body coil, or may be separate surface coils, is further controlled by a transmit/receive (T/R) switch 413. The multiple gradient coils 402 and the RF coils are powered by a power supply unit 412. A transport system 404, for example a patient table, is used to position a subject 405, for example a patient, within the MR imaging system. A control unit 408 controls the RF coils 403 and the gradient coils 402. The control unit 408, though shown as a single unit, may be implemented as multiple units as well. The control unit 408 further controls the operation of a reconstruction unit 409. The control unit 408 also controls a display unit 410, for example a monitor screen or a projector, a data storage unit 415, and a user input interface unit 411, for example, a keyboard, a mouse, a trackball, etc.

The main coils 401 generate a steady and uniform static magnetic field, for example, of field strength 1 T, 1.5 T or 3 T. The disclosed RF coil array with a charging circuit may be employed at other field strengths as well. The main coils 401 are arranged in such a way that they typically enclose a tunnel-shaped examination space, into which the subject 405 may be introduced. Another common configuration comprises opposing pole faces with an air gap in between them into which the subject 405 may be introduced by using the transport system 404. To enable MR imaging, temporally variable magnetic field gradients superimposed on the static magnetic field are generated by the multiple gradient coils 402 in response to currents supplied by the gradient driver unit 406. The power supply unit 412, fitted with electronic gradient amplification circuits, supplies currents to the multiple gradient coils 402, as a result of which gradient pulses (also called gradient pulse waveforms) are generated. The control unit 408 controls the characteristics of the currents, notably their strengths, durations and directions, flowing through the gradient coils to create the appropriate gradient waveforms. The control unit 408 also controls, via the T/R switch 413, the application of RF pulse excitations and the reception of MR signals comprising echoes, free induction decays, etc. The RF coils 403 generate RF excitation pulses in the subject 405 and receive MR signals generated by the subject 405 in response to the RF excitation pulses. The RF coil driver unit 407 supplies current to the RF coil 403 to transmit the RF excitation pulse, and amplifies the MR signals received by the RF coil 403. The transmitting and receiving functions of the RF coil 403 or set of RF coils are controlled by the control unit 408 via the T/R switch 413. The T/R switch 413 is provided with electronic circuitry that switches the RF coil 403 between transmit and receive modes, and protects the RF coil 403 and other associated electronic circuitry against breakthrough or other overloads, etc. The characteristics of the transmitted RF excitation pulses, notably their strength and duration, are controlled by the control unit 408. The control unit 408 also generates the control signal to operate the switching circuit (102sw1 and 102sw2, 104sw1 and 104sw2, 106sw1 and 106sw2, 108sw1 and 108sw2 in FIG. 1), based on the MR pulse sequence. By operating the switching circuits, the control unit 408 may switch the charging circuit from charging mode (to charge the rechargeable power supply devices) and “RF-invisible” mode (to prevent the flow of common-mode currents during RF transmit and/or receive operations).

It is to be noted that though the transmitting and receiving coil are shown as one unit in this embodiment, it is also possible to have separate coils for transmission and reception, respectively. It is further possible to have multiple RF coils 403 for transmitting or receiving or both. The RF coils 403 may be integrated into the magnet in the form of a body coil, or may be separate surface coils. They may have different geometries, for example, a birdcage configuration or a simple loop configuration, etc. The control unit 408 is preferably in the form of a computer that includes a processor, for example a microprocessor. User input interface devices 411 like a keyboard, mouse, touch-sensitive screen, trackball, etc., enable an operator to interact with the MR system.

The MR signal received with the RF coils 403 contains the actual information concerning the local spin densities in a region of interest of the subject 405 being imaged. The received signals are reconstructed by the reconstruction unit 409, and displayed on the display unit 410 as an MR image or an MR spectrum. It is alternatively possible to store the signal from the reconstruction unit 409 in a storage unit 415, while awaiting further processing. The reconstruction unit 409 is constructed advantageously as a digital image-processing unit that is programmed to derive the MR signals received from the RF coils 403.

The control unit 408 is capable of loading and running a computer program comprising instructions that, when executed on the computer, enables the computer to execute the various aspects of the methods disclosed herein. The computer program disclosed herein may reside on a computer readable medium, for example a CD-ROM, a DVD, a floppy disk, a memory stick, a magnetic tape, or any other tangible medium that is readable by the computer. The computer program may also be a downloadable program that is downloaded, or otherwise transferred to the computer, for example via the Internet. The transfer means may be an optical drive, a magnetic tape drive, a floppy drive, a USB or other computer port, an Ethernet port, etc.

The order in the described embodiments of the disclosed methods is not mandatory. A person skilled in the art may change the order of steps or perform steps concurrently using threading models, multi-processor systems or multiple processes without departing from the disclosed concepts.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A radio-frequency coil array for receiving a magnetic resonance signal, the radio-frequency coil array comprising:
at least one radio-frequency receive coil with an associated electronic circuit;
a rechargeable electrical storage device arranged to supply electrical power to the associated electronic circuit; and
a charging circuit arranged to charge the rechargeable electrical storage device, wherein the charging circuit includes a switching circuit configured to electrically isolate the charging circuit from the radio-frequency coil array at least when the radio-frequency receive coil is in operation.

2. The radio-frequency coil array of claim 1, wherein the rechargeable electrical storage device is a supercapacitor.

3. The radio-frequency coil array of claim 1, wherein the charging circuit is configured to generate multiple voltages.

4. A magnetic resonance system including a radio-frequency coil array as claimed in claim 1, wherein the radio-frequency coil array is arranged to receive a magnetic resonance signal, the radio-frequency coil array comprising:
at least one radio-frequency receive coil with an associated electronic circuit;
a rechargeable electrical storage device arranged to supply electrical power to the associated electronic circuit; and
a charging circuit arranged to charge the rechargeable electrical storage device, wherein the charging circuit includes a switching circuit configured to electrically isolate the charging circuit from the radio-frequency coil array at least when the radio-frequency receive coil is in operation.

5. The magnetic resonance system of claim 4, including a radio-frequency transmit coil arranged to transmit radio-frequency signals to a subject, wherein the switching circuit is further configured to isolate the charging circuit when the radio-frequency transmit coil is transmitting radio-frequency signals.

6. A method of supplying electrical power to a radio-frequency coil array in a magnetic resonance system, wherein the radio-frequency coil array comprises at least one radio-frequency receive coil with an associated electronic circuit, and wherein a rechargeable electrical storage device is configured to supply electrical power to the associated electronic circuit, the method comprising:
operating a charging circuit to charge the rechargeable electrical storage device, wherein the charging circuit includes a switching circuit; and
operating the switching circuit to isolate the charging circuit from the radio-frequency coil array at least when the radio-frequency receive coil is in operation.

7. A method of operating a radio-frequency coil array as claimed in claim 6, the magnetic resonance system including a radio-frequency transmit coil arranged to transmit radio-frequency signals to a subject, the method further comprising:
operating the switching circuit to isolate the charging circuit from the radio-frequency coil array when the radio-frequency transmit coil is transmitting radio-frequency signals to the subject.

8. A computer program to implement a method of supplying electrical power to a radio-frequency coil array in a magnetic resonance system, wherein the radio-frequency coil array comprises at least one radio-frequency receive coil with an associated electronic circuit and wherein a rechargeable electrical storage device is configured to supply electrical power to the associated electronic circuit, the computer program comprising instructions to:
operate a charging circuit to charge the rechargeable electrical storage device; and
operate a switching circuit to isolate the charging circuit from the radio-frequency coil array at least when the radio-frequency receive coil is in operation, when the computer program is run on a computer.

9. The computer program of claim 8, the magnetic resonance system including a radio-frequency transmit coil arranged to transmit radio-frequency signals to a subject, the computer program further comprising instructions to:
operate the switching circuit to isolate the charging circuit from the radio-frequency coil array when the radio-frequency transmit coil is transmitting radio-frequency signals to the subject.
